(19) United States
(12) Patent Application Publication
(10) Pub. No.: US 2026/0235644 A1
(43) Pub. Date: Aug. 13, 2026

(54) PROBE ASSEMBLY FOR TEST AND BURN-IN HAVING A CONTACT PROBE

(71) Applicant: KES SYSTEMS & SERVICE (1993) PTE LTD., Singapore (SG)

(72) Inventors: Hock Soon Sim, Singapore (SG); Zhiyun Ke, Singapore (SG)

(21) Appl. No.: 19/155,334

(22) PCT Filed: Feb. 8, 2024
(86) PCT No.: PCT/SG2024/050071

§ 371 Date: Aug. 11, 2025

Related U.S. Application Data
(60) Provisional application No. 63/445,149, filed on Feb. 13, 2023.

(51) Int. Cl. G01R 1/067; G01R 31/28

(52) U.S. Cl. CPC G01R 1/067; G01R 31/2875

(57) ABSTRACT

A probe assembly having at least one guide plate, the guide plate having a plurality of holes. There is at least one probe extending through at least one hole in the guide plate. The at least one probe has a catch structure on its proximal end for suspending the probe in the hole of the guide plate and preventing it from passing therethrough. The catch structure is selected from the group consisting of a flange and a bent portion.

### CROSS-REFERENCE TO RELATED APPLCATIONS

This application claims priority to and the benefit of U.S. Provisional Application No. 63/445,149, which was filed on Feb. 13, 2023, and is incorporated by reference herein.

### TECHNICAL FIELD

Described is a probe assembly for test and burn-in having a contact probe.

### BACKGROUND

Wafers containing thousands to a few hundred thousand integrated circuit die are subjected to various electrical tests. These electrical tests are designed to identify bad die on the wafer prior to singulation into individual die (i.e., chips) for insertion into a final package. Examples of such packages include a quad flat package (QFP), a quad flat, no lead package (QFN), a ball grid array (BGA), and a wafer level chip scale package (WLCSP). The separation of good and bad individual die is carried out in a wafer sort test system.

A typical wafer sort test system (e.g., within a test cell) includes a tester for generating various electrical test signals, a test head for receiving and transferring the test signals from the tester, a prober interface board for receiving and transferring the test signals from the test head, and a probe card for receiving and transferring the test signals from the prober interface board. The probe card may be used to make temporary electrical contact with a wafer. A wafer prober may be used to position the wafer relative to the probe card.

During a wafer sort test, the tester generates and measures various electrical test signals that consist of specific combinations of voltage, current and frequency. These electrical test signals are transmitted from the tester to the test head, to the prober interface board, to the probe card and then to one or more integrated circuits on the wafer. The integrated circuit response to electrical signals, such as voltage, current and frequency, are measured, analyzed and compared by the tester. These electrical values received from a specific integrated circuit that do not meet a specification will be identified as “bad” in the software.

Probe cards may include a printed circuit board (PCB) or space transformer and a probe head (referred to herein as a probe assembly) that contains contact elements, such as probes, for making temporary electrical contact with the contact pads on the wafer (i.e., the device under test (DUT)) and contact pads on the PCB or space transformer. During operation, the wafer prober may align the X-Y position of a wafer die with the probe card's X-Y position prior to the start of any electrical test. The wafer prober may then raise the wafer toward the probe card in a positive Z-direction until the probes touch the contact pads of the wafer die. The wafer prober may then apply an overdrive force and raise the wafer a further distance (e.g., a few more millimeters in a positive Z-direction) to make sure all the probes are brought into contact with the respective contact pads of the wafer die with sufficient force. Sufficient force is adequate force to ensure good electrical contact between the probes and the wafer contact pads. Also, during operation, the probes are brought into contact with the contact pads on the PCB or space transformer. Once an electrical test is completed on a particular wafer die, the wafer is stepped in sequence to the rest of the untested die on the wafer.

One problem that arises in electrical test assemblies is that, when a wafer die draws more power, especially for power device applications, the probe may be burnt. The electrical current may not travel through the probe of the probe assembly in the shortest possible path (e.g., lowest ohmic resistance path). Rather, the electrical current may travel through the probe in a longer and higher electrical resistance path that causes unnecessary heating of the probe.

Other problems may arise during the probe assembly installation onto a PCB or space transformer. For example, in some instances the probe assembly must to inverted prior to the installation onto the PCB. The inverted probe may fall out from the probe assembly due to gravity Solutions to the problems described above (e.g., burning of the probe due to high power testing and the probe falling out of the inverted probe assembly) are sought.

### BRIEF SUMMARY

Described herein is a probe assembly having at least one guide plate, the guide plate having a plurality of holes. There is at least one probe extending through at least one hole in the guide plate. The at least one probe has a catch structure on its proximal end for suspending the probe in the hole of the guide plate and preventing it from passing therethrough. The catch structure is selected from the group consisting of a flange and a bent portion.

In one aspect, the probe is resiliently compliant.

In a further aspect, the probe has a heat conductive serpentine structure that extends from the proximal end of the probe to a distal end. In any of the above aspects, the probe has first fingers extending from the proximal end of the probe. In a further aspect, the first fingers are in spaced relation to the serpentine structure such that a first gap between the fingers and the serpentine structure and the first fingers is larger than a second gap between the first fingers and the serpentine structure, wherein the first gap is closer to the proximal end of the probe than the second gap.

In a further aspect, the probe also has second fingers extending from the distal end of the probe, the second fingers in spaced relation to the serpentine structure such that there is a gap between the serpentine structure and the second fingers. In a further aspect, upon compression of the serpentine structure, the first fingers come into contact with the second fingers.

Also described herein is a method for testing an electrical device. According to the method, a probe assembly is provided, the probe assembly having at least one guide plate, the guide plate having a plurality of holes. The probe plate also has at least one probe extending through at least one hole in the guide plate. According to the method, at least one probe has a catch structure on its proximal end for suspending the probe in the hole of the guide plate and preventing it from passing therethrough. In one aspect, the catch structure is selected from the group consisting of a flange and a bent portion. Wherein, according to the method a proximal end of the probe is placed into engagement with a contact on a PCB or space transformer, wherein a distal end of the probe is placed into engagement with a contact on a wafer.

In one aspect of the method, the probe is resiliently compliant. In a further aspect, the probe has a heat conductive serpentine structure that extends from the proximal end of the probe to the distal end. In yet a further aspect, the probe has first fingers extending from the proximal end of the probe. According to the above aspects of the method, the first fingers are in spaced relation to the serpentine structure such that a first gap between the fingers and the serpentine structure and the first fingers is larger than a second gap between the first fingers and the serpentine structure, wherein the first gap is closer to the proximal end of the probe than the second gap.

In a further aspect, the probe has second fingers extending from the distal end of the probe, the second fingers in spaced relation to the serpentine structure such that there is a gap between the serpentine structure and the second fingers. According to the method, the serpentine structure is compressed between the PCB or space transformer and the wafer contact, thereby causing the first fingers to come into contact with the second fingers.

### BRIEF DESCRIPTION OF DRAWINGS

FIG. 1 illustrates an isometric view of a probe according to one implementation.

FIG. 2 is a front view of the probe in FIG. 1.

FIGS. 3(a) and 3(b) are a front view of the probe in FIG. 1 with each of upper fingers having a tip structure.

FIG. 4 illustrates heat distribution on the probe in FIG. 1, when electrical current is flowing therethrough.

FIG. 5 illustrates heat distribution on probe in FIG. 1 with the upper fingers engaged with the lower fingers, when electrical current is flowing therethrough.

FIG. 6 illustrates a front view of a probe according to another implementation.

FIG. 7 illustrates an upper portion of the probe in FIG. 6.

FIG. 8(a)-8(c) illustrate the probe in FIG. 6 which has been inserted into a hole of a guide plate.

### DETAILED DESCRIPTION

Implementations of the present disclosure are described in detail with reference to the drawing figures wherein like reference numerals identify similar or identical elements. It is to be understood that the disclosed implementations are merely examples of the disclosure, which may be embodied in various forms. Well-known functions or constructions are not described in detail to avoid obscuring the present disclosure in unnecessary detail. Therefore, specific structural and functional details disclosed herein are not to be interpreted as limiting, but merely as a basis for the claims and as a representative basis for teaching one skilled in the art to variously employ the present disclosure in virtually any appropriately detailed structure.

Various electrically conductive probes for use in a probe assembly are described herein. The probes may be patterned structures that are resiliently compliant. Resiliently compliant, as used herein, means that the probes, when subjected to a force that bends or otherwise deforms the probe, will revert to their original shape when the deformation force is no longer applied. The probes have a proximal end and a distal end. During operation, the proximal end of a probe is placed into engagement with a contact on a PCB or space transformer, and the distal end of the probe is placed into engagement with a contact on a wafer (i.e., a DUT).

The probe assembly may have one or more guide plates (e.g., three plates). The one or more guide plates may be formed from an electrically non-conductive (i.e., electrically insulating) material, such as ceramic, plastic, glass, fused silica, etc. When multiple guide plates are employed in the probe assembly, each guide plate forms a plane with a plurality of holes therethrough forming an array of holes. The holes in the guide plates may be aligned vertically so that the electrically conductive probes may be held in the holes in the guide plates and extend therethrough. The holes may be square, rectangular, circular, or have any shape suitable for receiving the probes. During manufacturing, the holes may be formed through an etching and/or a laser drilling process. The guide plates are held at a distance defined by one or more spacers. Such spacers are conventional and well known to one skilled in the art. Therefore, the spacers are not described in detail herein. The spacers may be formed from any structurally suitable material, such as plastic. The spacers may also include layers of plastic and/or metal.

As noted above, each of the plurality of electrically conductive probes may be resiliently compliant, so that only the necessary force that is required for acceptable electrical contact is applied by the probe to an electrical contact (e.g., a contact on a PCB or space transformer and/or a contact of a wafer). For example, the probes may have some degree of resilient compliance such that, in response to a predetermined load placed on the probe when advanced into electrical connectivity with an electrical contact, the probe will deform, which limits or mitigates the amount of force that the probe can apply to the electrical contact. During operation, the probe assembly may be preloaded. For example, before the distal ends of any of the probes are placed into engagement with the contact pads on a wafer, the proximal ends of the probes may be placed into engagement with the contact pads on a PCB or space transformer. After preloading the probe assembly, an upper portion of each of the probes may deform. Furthermore, after contacting a wafer during testing, a lower portion of each of the probes may deform.

The electrically conductive probes may be constructed from a homogenous alloy, such as silver-copper alloy, platinum alloy, palladium alloy, etc., or a composite of different layers of materials, such as copper, gold, rhodium, nickel, nickel alloy, graphene, carbon nano tube, etc. Material selection will depend on the electrical and mechanical strength probe requirements. In some implementations, the fabrication process of such probes may include, for example, laser cutting a metal foil or sheet and/or additive manufacturing methods, such as electroforming, covalent bonding, and/or etching. In some implementations, after one or more such processes, the fabrication process may also include adding one or more layers of materials to the probes while they rest on one or more flat horizontal surfaces. These manufacturing techniques may be used to produce probes having, for example, square and/or rectangular cross sections. During manufacturing, the probes may also be stamped to form a curved portion. In some implementations, the probes may be formed using Micro-Electro-Mechanical Systems (MEMS) manufacturing techniques. In some implementations, the probes may be coated with one or more layers of electrically insulating materials, such as acrylic, polyimides, parylene, and/or any other electrically insulating materials.

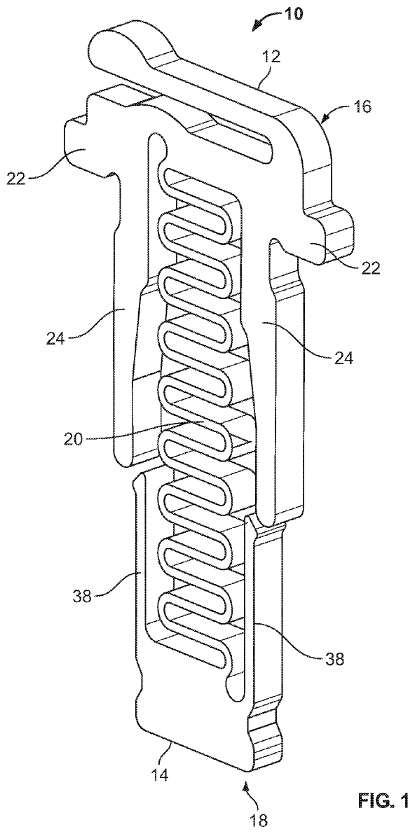

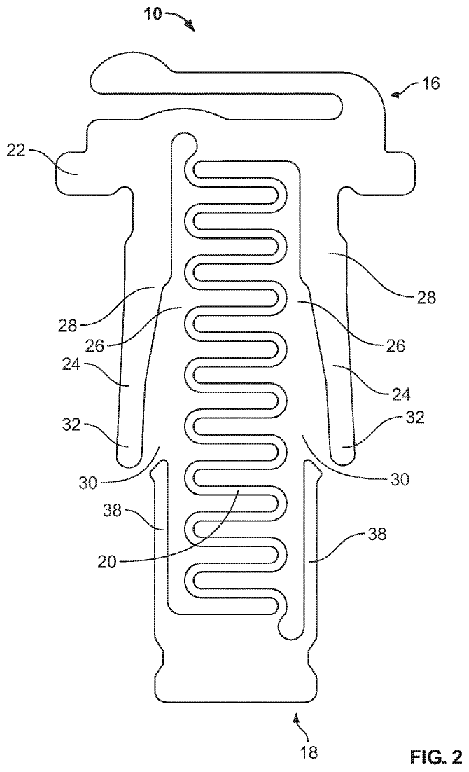

FIGS. 1 and 2 illustrate an isometric view and a front view, respectively, of a probe 10 having a proximal end 12 and a distal end 14. The probe 10 extends between the proximal and distal ends 12, 14 and includes an upper portion 16, a lower portion 18, a middle portion 20 that integrally connects the upper and lower portions 16, 18. As shown in FIGS. 1 and 2, the middle portion 20 of the probe 10 is serpentine-shaped or spiral-shaped (e.g., spring-like) such that the probe 10 may be compressed during an electrical test. For example, when the lower portion 18 of the probe 10 is pushed upward from the distal end 14 by the upward force of a contact pad of a wafer (not shown), the serpentine or spiral-shaped middle portion 20 gives or compresses, thereby permitting the probe 10 to be compressed. Likewise, when the upward force or load of a contact pad of a wafer is removed, the shaped middle portion 20 allows the probe 10 to relax back to its original shape.

The upper portion 16 of the probe 10 includes a stopper structure 22 for preventing the probe 10 from falling downward through the holes in the guide plates and out of the probe assembly. The stopper structure 22 is a flange that extends laterally past the hole of the guide plate (not shown), when the probe 10 is inserted therethrough. Since the flange cannot pass through the hole of the guide plate, the probe 10 may be held in the probe assembly. As a result, the flange prevents the probe 10 from falling through the guide plate (not shown) when there is nothing beneath the probe assembly that would prevent the probe 10 from otherwise traveling through the hole in the guide plate and falling out of the probe assembly (e.g., from gravity and/or a force applied to a proximal end of the probe through a PCB or space transformer). In other words, the stopper structure serves to suspend the probe 10 in the probe assembly.

Referring again to FIGS. 1 and 2, the upper portion 16 of the probe 10 further includes a pair of upper fingers 24 that extend from the distal end 14 of the probe 10. The pair of upper fingers 24 are constructed and designed such that they allow the probe 10 to be firmly engaged with a guide plate (not shown), when the probe 10 is inserted into the guide plate. For example, as shown in FIG. 2, each of the pair of upper fingers 24 extends downwardly from the bottom of the upper portion 16 in an angle such that a first gap 26 (formed between a first end portion 28 of the upper finger 24 and the middle portion 20) is smaller than a second gap 30 formed between a second end portion 32 of the upper finger 24 and the middle portion 20. Thus, when the probe 10 is inserted into the hole of the guide plate, each upper finger 24 bends slightly inward and towards the middle portion 20 of the probe 10 and, concurrently, exerts an outward force away from the middle portion 20 as each upper finger is biased. The outward force from each upper finger 24 allows the probe 10 to be firmly engaged with the guide plate and retained in the probe assembly. Thus, the probe assembly with the probe 10 having the upper fingers 24 (shown in FIG. 2) requires only one guide plate for retaining the probe 10 therewithin.

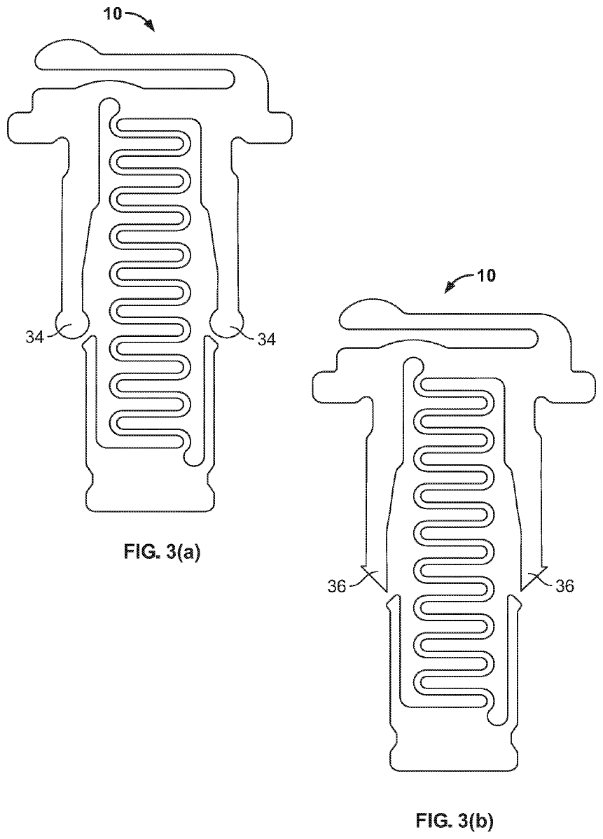

Referring to FIGS. 3(a) and (b), each of the upper fingers 24 may include a tip structure 34, 36. The tip structure 34, 36 provides a locking mechanism that allows the probe 10 to be locked with the bottom of the guide plate when the probe 10 is fully inserted and is passed through the hole of the guide plate. Thus, the tip structure 34, 36 prevents the probe 10 from falling out of the probe assembly when the probe assembly is inverted. Although, the tip structure 34, 36 is round-shaped 34 or hook-shaped 36, as shown in FIGS. 3(a) and (b), respectively, it is contemplated that the tip structure 34, 36 may be in any shape suitable for providing a locking mechanism for the probe 10.

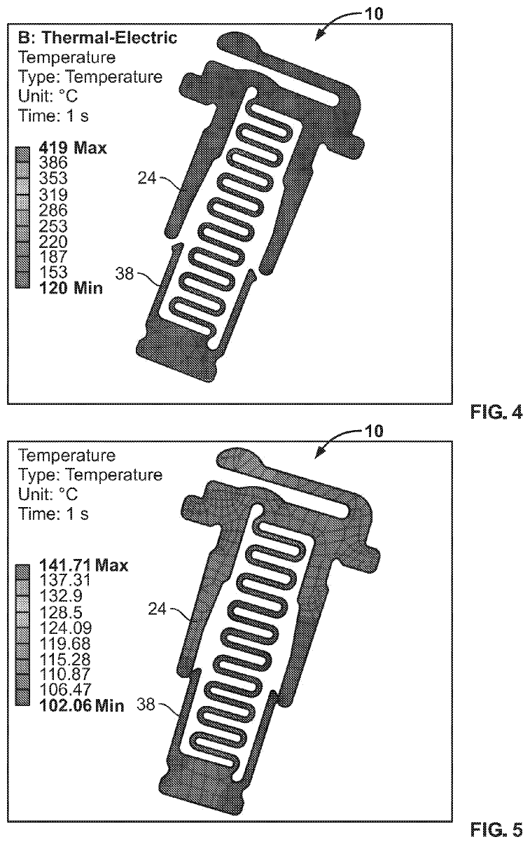

Referring again to FIGS. 1 and 2, the lower portion 18 of the probe 10 includes a pair of lower fingers 38. Each of the lower fingers 38 extends upwardly from the lower portion 18 of the probe 10. During operation, when the probe 10 is sufficiently compressed, each lower finger 38 engages (or makes a contact) with its respective upper finger 24 by sliding into the gap 30 between the upper finger 24 and the middle portion 20, as shown in FIG. 5. Engagement of the upper and lower fingers 24, 38 provides a shorter electrical path for the electrical current to flow through the probe 10, thereby preventing high heat distribution on the probe 10. Specifically, when the upper and lower fingers 24, 38 for the probe 10 are disengaged, the electrical current flowing through the probe 10 causes high heat distribution on the probe 10 (about 400 degrees Celsius), as shown in FIG. 4, whereas when the upper and lower fingers 24, 38 of the probe 10 are engaged, the electrical current flowing through the probe 10 causes the temperature to be dropped (to about 140 degrees Celsius), as shown in FIG. 5.

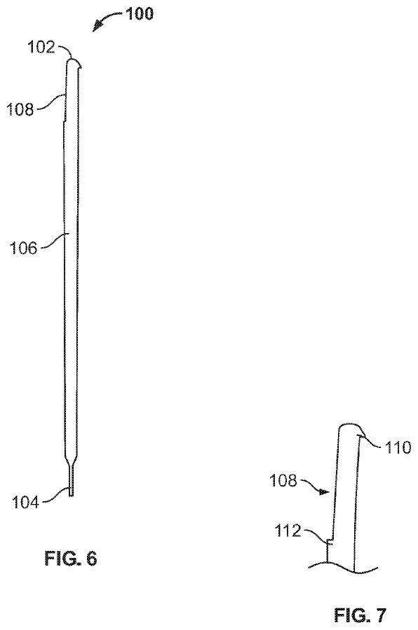

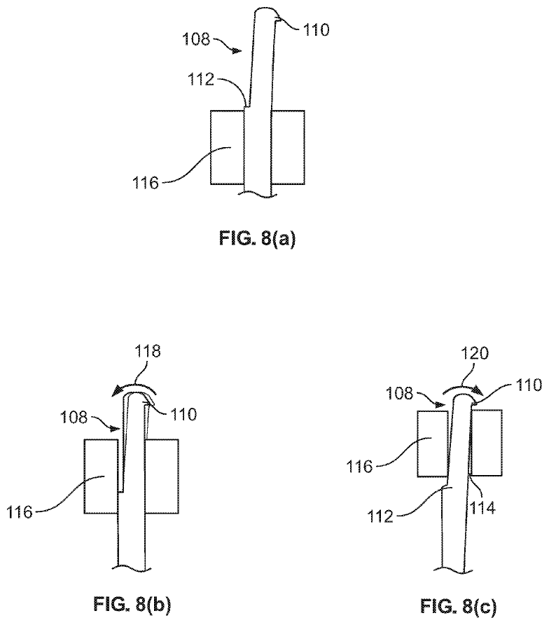

FIG. 6 illustrates a probe 100 according to another implementation. The probe 100 includes a proximal end 102 and a distal end 104 and extends therebetween. The probe 100 further includes a lower portion 106 and an upper portion 108 that is slightly bent with a stopper structure 110 formed at the top of the upper portion 108 and a latch 112 formed at the bottom of the upper portion 108, as shown in FIG. 7. When the probe 100 is fully inserted into the hole 114 of the top guiding plate 116, as shown in FIG. 8(c), and into the hole of the bottom plate (not shown), the stopper structure 110 is positioned immediately above the top of the top guide plate 116, thereby preventing the probe 100 from falling through the guide plate when there is nothing beneath the probe assembly that would prevent the probe 100 from otherwise traveling through the hole in the guide plate and falling out of the probe assembly. The latch 112 is positioned immediately below the bottom of the top guide plate 116, thereby preventing the probe 100 from falling out of the assembly when the probe assembly is inverted.

As stated above, the upper portion 108 of the probe 100 is slightly bent. Thus, as the upper portion 108 is inserted into the hole 114 of the top guide plate 116, as shown in FIGS. 8(a) and (c), the upper portion 108 is first forced to move away from the inner wall of the hole 114 in the direction of the arrow 118 due to the upper portion 108 being in contact with the inner wall of the hole 114. As the upper portion 108 of the probe 110 is further inserted in the hole 114 of the top guide plate 116, the upper portion 108 exerts an inward force and moves toward the inner wall in the direction of the arrow 120 as the upper portion 108 is biased. Once the upper portion 108 of the probe 100 is fully inserted into the hole 114 and passes therethrough, as shown in FIG. 8(c), the stopper structure 110 and the latch 112 are positioned immediately above the top guide plate 116 and below the top guide plate 116, respectively.

The amount of force applied by the proximal and distal ends of the probe illustrated in FIGS. 1 and 6 to the contact pads of the PCB or space transformer (not shown) and the wafer (not shown), respectively, depends on the dimensions of the probe and the type of material used to construct the probe. Such calculations are conventional and well known to one skilled in the art. Therefore, these calculations are not described in detail herein.

The probes disclosed herein are dimensioned such that they provide a sufficient amount of conductance for the probe assembly. The amount of conductance required for a specific apparatus is largely a matter of design choice and is not discussed in detail herein. The probes are dimensioned to be resilient. As described in detail herein, the apparatus allows for the probes to bend as either the PCB/space transformer or a test wafer is advanced into contact with the probes for testing. After testing, when the PCB/space transformer or test wafer is removed from contact with the probe, the probe(s) relax to its original shape.

Described herein is a probe assembly having at least one guide plate, the guide plate having a plurality of holes and at least one probe extending through at least one hole in the guide plate. In this aspect, at least one probe has a catch structure on its proximal end for suspending the probe in the hole of the guide plate and preventing it from passing therethrough, wherein the catch structure is selected from the group consisting of a flange and a bent portion.

In one aspect, the probe is resiliently compliant.

In a further aspect, the probe has a heat conductive serpentine structure that extends from the proximal end of the probe to a distal end. In any of the above aspects, the probe has first fingers extending from the proximal end of the probe. In a further aspect, the first fingers are in spaced relation to the serpentine structure such that a first gap between the fingers and the serpentine structure and the first fingers is larger than a second gap between the first fingers and the serpentine structure, wherein the first gap is closer to the proximal end of the probe than the second gap.

In a further aspect, the probe also has second fingers extending from the distal end of the probe, the second fingers in spaced relation to the serpentine structure such that there is a gap between the serpentine structure and the second fingers. In a further aspect, upon compression of the serpentine structure, the first fingers come into contact with the second fingers.

Also described herein is a method for testing an electrical device. According to the method, a probe assembly is provided, the probe assembly having at least one guide plate, the guide plate having a plurality of holes. The probe plate also has at least one probe extending through at least one hole in the guide plate. According to the method, at least one probe has a catch structure on its proximal end for suspending the probe in the hole of the guide plate and preventing it from passing therethrough. In one aspect, the catch structure is selected from the group consisting of a flange and a bent portion. Wherein, according to the method a proximal end of the probe is placed into engagement with a contact on a PCB or space transformer, wherein a distal end of the probe is placed into engagement with a contact on a wafer.

In one aspect of the method, the probe is resiliently compliant. In a further aspect, the probe has a heat conductive serpentine structure that extends from the proximal end of the probe to the distal end. In yet a further aspect, the probe has first fingers extending from the proximal end of the probe. According to the above aspects of the method, the first fingers are in spaced relation to the serpentine structure such that a first gap between the fingers and the serpentine structure and the first fingers is larger than a second gap between the first fingers and the serpentine structure, wherein the first gap is closer to the proximal end of the probe than the second gap.

In a further aspect, the probe has second fingers extending from the distal end of the probe, the second fingers in spaced relation to the serpentine structure such that there is a gap between the serpentine structure and the second fingers. According to the method, the serpentine structure is compressed between the PCB or space transformer and the wafer contact, thereby causing the first fingers to come into contact with the second fingers.

From the foregoing and with reference to the various figure drawings, those skilled in the art will appreciate that certain modifications can also be made to the present disclosure without departing from the scope of the same. While several implementations of the disclosure have been shown in the drawings, it is not intended that the disclosure be limited thereto, as it is intended that the disclosure be as broad in scope as the art will allow and that the specification be read likewise. Therefore, the above description should not be construed as limiting, but merely as exemplifications of particular implementations. Those skilled in the art will envision other modifications within the scope and spirit of the claims appended hereto.

1. A probe assembly comprising:
at least one guide plate, the guide plate having a plurality of holes;
at least one probe extending through at least one hole in the guide plate; and
the at least one probe comprising a catch structure on its proximal end for suspending the probe in the hole of the guide plate and preventing it from passing therethrough, wherein the catch structure is selected from the group consisting of a flange and a bent portion.

2. The probe assembly of claim 1, wherein the probe is resiliently compliant.

3. The probe assembly of claim 1, where the probe has a heat conductive serpentine structure that extends from the proximal end of the probe to a distal end.

4. The probe assembly of claim 1, wherein the probe has first fingers extending from the proximal end of the probe.

5. The probe assembly of claim 3, where the first fingers are in spaced relation to the serpentine structure such that a first gap between the fingers and the serpentine structure and the first fingers is larger than a second gap between the first fingers and the serpentine structure, wherein the first gap is closer to the proximal end of the probe than the second gap.

6. The probe assembly of claim 4, wherein the probe further comprises second fingers extending from the distal end of the probe, the second fingers in spaced relation to the serpentine structure such that there is a gap between the serpentine structure and the second fingers.

7. The probe assembly of claim 4, wherein, upon compression of the serpentine structure, the first fingers come into contact with the second fingers.

8. A method for testing an electrical device, the method comprising:
providing a probe assembly comprising:
at least one guide plate, the guide plate having a plurality of holes;
at least one probe extending through at least one hole in the guide plate;
wherein the at least one probe comprises a catch structure on its proximal end for suspending the probe in the hole of the guide plate and preventing it from passing therethrough, wherein the catch structure is selected from the group consisting of a flange and a bent portion; and
placing a proximal end of the probe into engagement with a contact on a PCB or space transformer, wherein a distal end of the probe is placed into engagement with a contact on a wafer.

9. The method of claim 8, wherein the probe is resiliently compliant.

10. The method of claim 8, where the probe has a heat conductive serpentine structure that extends from the proximal end of the probe to the distal end.

11. The method of claim 8, wherein the probe has first fingers extending from the proximal end of the probe.

12. The method of claim 10, where the first fingers are in spaced relation to the serpentine structure such that a first gap between the fingers and the serpentine structure and the first fingers is larger than a second gap between the first fingers and the serpentine structure, wherein the first gap is closer to the proximal end of the probe than the second gap.

13. The method of claim 10, wherein the probe further comprises second fingers extending from the distal end of the probe, the second fingers in spaced relation to the serpentine structure such that there is a gap between the serpentine structure and the second fingers.

14. The method of claim 13, further comprising compressing the serpentine structure between the PCB or space transformer and the wafer contact, thereby causing the first fingers to come into contact with the second fingers.
